(19) United States
(12) Patent Application Publication
(10) Pub. No.: US 2011/0212590 A1
(43) Pub. Date: Sep. 1, 2011

(54) HIGH TEMPERATURE IMPLANTATION METHOD FOR STRESSOR FORMATION

(75) Inventors: Chii-Ming Wu, Taipei City (TW); Chun-Feng Nieh, Baoshan Township (TW)

(73) Assignee: TAIWAN SEMICONDUCTOR MANUFACTURING COMPANY, LTD., Hsin-Chu (TW)

(21) Appl. No.: 12/713,735

(22) Filed: Feb. 26, 2010

(51) Int. Cl. H01L 21/336; H01L 21/265

(52) U.S. Cl. 438/303; 438/530; 257/E21.334; 257/E21.409

(57) ABSTRACT

An integrated circuit device and method of fabricating the integrated circuit device is disclosed. According to one of the broader forms of the invention, a method involves providing a semiconductor substrate. A combination of a pre-amorphous implantation process, a high temperature carbon implantation process, and/or an annealing process are performed on the substrate to form a stressor region.

### BACKGROUND

The semiconductor integrated circuit (IC) industry has experienced rapid growth. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC manufacturing are needed.

For example, as semiconductor devices, such as a metal-oxide-semiconductor field-effect transistors (MOSFETs), are scaled down through various technology nodes, strained source/drain features (e.g., stressor regions) have been implemented using epitaxial (epi) semiconductor materials to enhance carrier mobility and improve device performance. Forming a MOSFET with stressor regions could include epitaxially growing a silicon layer in a source and drain region of an n-type device (and implanting the silicon layer with carbon), and epitaxially growing a silicon germanium layer (SiGe) in a source and drain region of a p-type device. Another technique for forming stressor regions is solid phase epitaxy (SPE), which involves implanting a source and drain region of a substrate to form amorphized regions, and thereafter, annealing the substrate, such that the amorphized regions re-crystallize. Although existing approaches to forming stressor regions for IC devices have been generally adequate for their intended purposes, they have not been entirely satisfactory in all respects.

### SUMMARY

The present disclosure provides for many different embodiments. According to one of the broader forms of the invention, a method includes providing a semiconductor substrate; performing a pre-amorphous implantation process on the substrate; performing a high temperature implantation process utilizing a temperature greater than about 200° C. on the substrate; and performing an annealing process on the substrate.

According to another of the broader forms of the invention, a method includes forming a gate structure over a substrate and forming a source and drain region in the substrate, adjacent the gate structure. A pre-amorphous implantation process and high temperature carbon implantation process are performed on the source and drain region.

According to another of the broader forms of the invention, a method includes forming a gate structure over a substrate; forming a source and drain region in the substrate, adjacent the gate structure; forming an amorphized region in the source and drain region; implanting the amorphized region utilizing a temperature equal to or greater than about 200° C.; and thereafter, performing a annealing process at a temperature greater than about 900° C., such that the amorphized region re-crystallizes and forms a stressor region.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for fabricating an integrated circuit device according to aspects of the present disclosure; and

FIGS. 2-5 are various cross-sectional views of embodiments of an integrated circuit device during various fabrication stages according to the method of FIG. 1.

### DETAILED DESCRIPTION

The present disclosure relates generally to integrated circuit devices and methods for manufacturing integrated circuit devices, and more particularly, to methods for reducing defects in integrated circuit devices.

It is understood that the following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

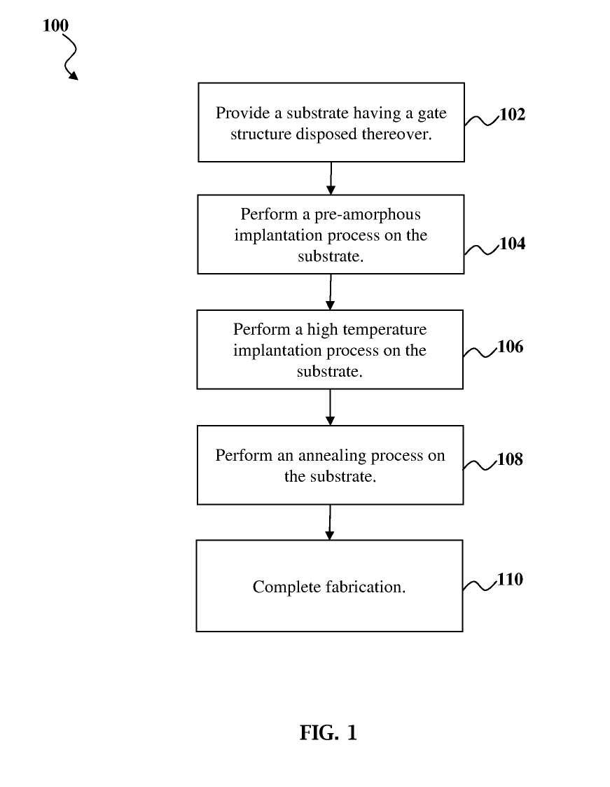

With reference to FIGS. 1 and 2-5, a method 100 and a semiconductor device 200 are collectively described below. The semiconductor device 200 illustrates an integrated circuit, or portion thereof, that can comprise memory cells and/or logic circuits. The semiconductor device 200 can include active components, such as metal-oxide-semiconductor field effect transistors (MOSFETs), complementary metal-oxide-semiconductor transistors (CMOSs), high voltage transistors, and/or high frequency transistors; other suitable components; and/or combinations thereof. The semiconductor device 200 may additionally include passive components, such as resistors, capacitors, inductors, and/or fuses. It is understood that the semiconductor device 200 may be formed by CMOS technology processing, and thus some processes are not described in detail herein. Additional steps can be provided before, during, and after the method 100, and some of the steps described below can be replaced or eliminated, for additional embodiments of the method. It is further understood that additional features can be added in the semiconductor device 200, and some of the features described below can be replaced or eliminated, for additional embodiments of the semiconductor device 200.

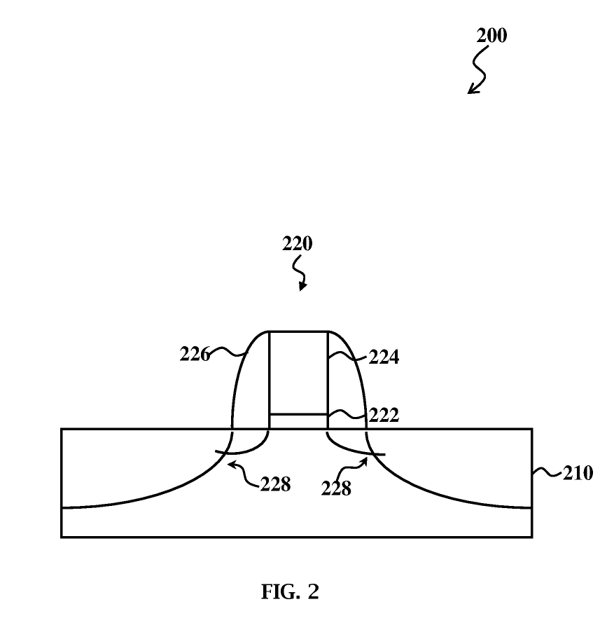

Referring to FIGS. 1 and 2, the method 100 begins at block 102, and a substrate 210 is provided. In the present embodiment, the substrate 210 is a semiconductor substrate including silicon. Alternatively, the substrate 210 includes an elementary semiconductor including silicon and/or germanium in crystal; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Where the substrate 210 is an alloy semiconductor, the alloy semiconductor substrate could have a gradient SiGe feature in which the Si and Ge composition change from one ratio at one location to another ratio at another location of the gradient SiGe feature. The alloy SiGe could be formed over a silicon substrate, and/or the SiGe substrate may be strained. In yet another alternative, the semiconductor substrate could be a semiconductor on insulator (SOI).

The substrate 210 includes various doped regions depending on design requirements as known in the art (e.g., p-type wells or n-type wells). The doped regions are doped with p-type dopants, such as boron or BF₂, and/or n-type dopants, such as phosphorus or arsenic. The doped regions may be formed directly on the substrate 210, in a P-well structure, in a N-well structure, in a dual-well structure, or using a raised structure. The doped regions include various active regions, such as regions configured for an N-type metal-oxide-semiconductor transistor (referred to as an NMOS) and regions configured for a P-type metal-oxide-semiconductor transistor (referred to as a PMOS).

The substrate 210 can include an isolation region to define and isolate various active regions of the substrate 210. The isolation region utilizes isolation technology, such as shallow trench isolation (STI) or local oxidation of silicon (LOCOS), to define and electrically isolate the various regions. The isolation region includes silicon oxide, silicon nitride, silicon oxynitride, other suitable materials, or combinations thereof.

The substrate 210 includes a gate structure 220 disposed thereover. The gate structure 220 includes various gate material layers. In the present embodiment, the gate material layers form a gate stack including a gate dielectric layer 222 and a gate layer 224 (also referred to as a gate electrode). The gate dielectric layer 222 is formed over the substrate 210 by any suitable process to any suitable thickness, and includes a dielectric material, such as silicon oxide, silicon oxynitride, silicon nitride, a high-k dielectric material layer, other suitable dielectric materials, and/or combinations thereof. Exemplary high-k dielectric materials include HfO₂, HfSiO, HfSiON, HfTaO, HfTiO, HfZrO, other suitable high-k dielectric materials, and/or combinations thereof. The gate dielectric layer 222 could include a multilayer structure. For example, the gate dielectric layer 222 includes an interfacial layer, and a high-k dielectric material layer formed on the interfacial layer. The interfacial layer is a grown silicon oxide layer formed by a thermal process or atomic layer deposition (ALD).

The gate layer 224 is formed over the gate dielectric layer 222 to a suitable thickness. In an example, the gate layer 224 is a polycrystalline silicon (or polysilicon) layer. The polysilicon layer may be doped for proper conductivity. Alternatively, the polysilicon is not necessarily doped, for example, if a dummy gate is to be formed and later replaced by a gate replacement process. In another example, the gate layer 224 is a conductive layer having a proper work function, therefore, the gate layer 224 can also be referred to as a work function layer. The work function layer includes a suitable material, such that the layer can be tuned to have a proper work function for enhanced performance of the device. For example, if a P-type work function metal (P-metal) for a PMOS device is desired, TiN or TaN may be used. On the other hand, if an N-type work function metal (N-metal) for an NMOS device is desired, Ta, TiAl, TiAlN, or TaCN, may be used. The work function layer could include doped conducting oxide materials. The gate layer 224 could include other conductive materials, such as aluminum, copper, tungsten, metal alloys, metal silicide, other suitable materials, and/or combinations thereof. The gate layer 224 could include multiple layers. For example, where the gate layer 224 includes a work function layer, another conductive layer can be formed over the work function layer. The gate layer 224 is formed by chemical vapor deposition (CVD), physical vapor deposition (PVD), atomic layer deposition (ALD), high density plasma CVD (HDPCVD), plating, other suitable methods, and/or combinations thereof.

The gate structure 220 further include spacers 226 disposed on sidewalls of the gate stack (i.e., gate dielectric layer 222 and gate layer 224). The gate spacers 226 include a dielectric material, such as silicon nitride, silicon oxide, silicon oxynitride, other suitable materials, and/or combinations thereof. The gate spacers 226 can be used to offset subsequently formed doped regions, such as heavily doped source/drain regions.

In the present embodiment, doped regions 228 are formed in the substrate 210. The doped regions 228 can include lightly doped source/drain (LDD) regions and/or source/drain (S/D) regions (also referred to as heavily doped S/D regions). The doped regions 228 are formed by ion implantation processes, photolithography processes, diffusion processes, annealing processes (e.g., rapid thermal annealing and/or laser annealing processes), and/or other suitable processes. The doping species depends on the type of device being fabricated and includes p-type dopants, such as boron or BF₂; n-type dopants, such as phosphorus or arsenic; and/or combinations thereof.

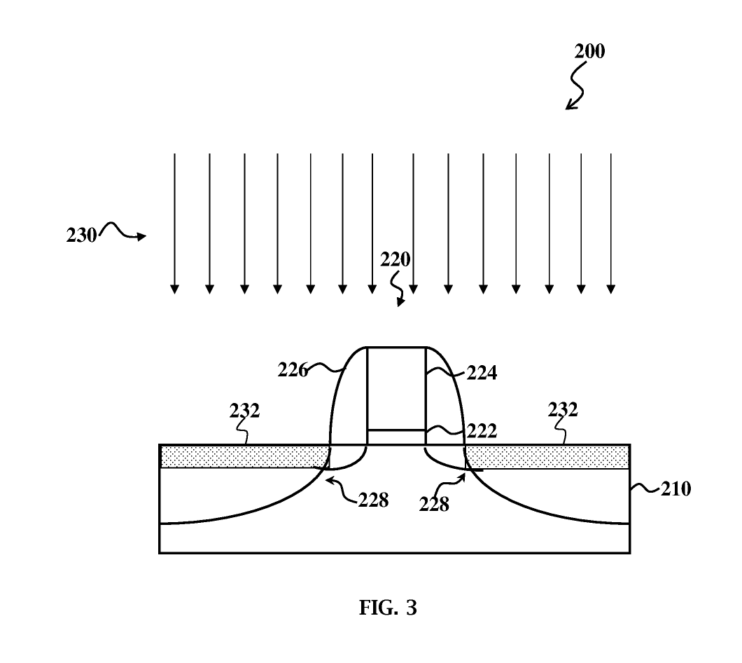

Referring to FIGS. 1 and 3, at block 104, a pre-amorphous implantation (PAI) process 230 is performed on the substrate 210. The PAI process 230 implants the substrate 210, damaging the lattice structure of the substrate 210 and forming amorphized regions 232. In the present embodiment, the amorphized regions 232 are formed in a source and drain region of semiconductor device 200, for example, doped regions 228. A patterned photoresist layer is utilized to define a stressor region (where amorphized regions 232 are formed) and protect other regions of the semiconductor device 200 from implantation damage. For example, the patterned photoresist layer exposes the doped regions 228, such that the doped regions 228 are exposed to the PAI process 230 (forming amorphized regions 232 in the doped regions 228) while the gate structure 220 (and other portions of semiconductor device 200) are protected from the PAI process 230. Alternatively, a patterned hard mask layer, such as a SiN or SiON layer, is utilized to define the stressor region.

The depth of the implantation can be controlled by the implant energy, implant species, and/or implant dosage. The PAI process 230 implants the substrate 210 with silicon (Si) or germanium (Ge). Alternatively, the PAI process 230 could utilize other implant species, such as Ar, Xe, BF₂, As, In, other suitable implant species, or combinations thereof. In the present embodiment, the PAI process 230 implants Si impurities at an implant energy from about 5 KeV to about 40 KeV, and a dosage ranging from about 1×10¹⁴ atoms/cm³ to about 2×10¹⁵ atoms/cm³.

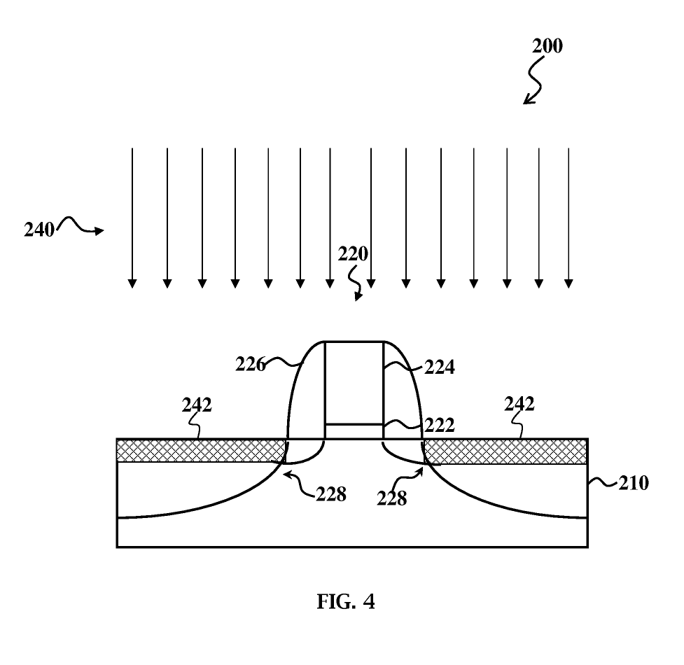

Referring to FIGS. 1 and 4, at block 106, a high temperature implantation process 240 is performed on the substrate 210. Similar to the PAI process 230, a patterned photoresist layer or patterned hard mask layer is utilized to define the stressor region (in the present embodiment, where the amorphized regions 232 have been formed). Accordingly, the patterned photoresist/hard mask layer exposes the doped regions 228 (and amorphized regions 232), such that the doped regions 228 are exposed to the high temperature implantation process 240 while the gate structure 220 (and other portions of semiconductor device 200) are protected from the high temperature implantation process 240. The patterned photoresist/hard mask layer can be the same patterned photoresist/hard mask layer used for the PAI process 230. Alternatively, the patterned photoresist/hard mask layer used in the PAI process 230 is subsequently removed, and a different patterned photoresist/hard mask layer is formed for the high temperature implantation process 240. The photoresist/hard mask layer is selected to withstand high temperature processes.

In the present embodiment, the semiconductor device 200 is an NMOS device, so the high temperature implantation process 240 utilizes a carbon implant species, forming regions 242 (e.g., Si:C regions). Alternatively, if the semiconductor device 200 is a PMOS device, the high temperature implantation process 240 utilizes a germanium implant species (forming SiGe regions). The high temperature implantation process 240 utilizes an energy from about 0.1 KeV to about 20 KeV and a dosage ranging from approximately 1×10¹³ atoms/cm³ to 1×10¹⁷ atoms/cm³. In the present embodiment, the high temperature carbon implantation utilizes a dosage of about 3×10¹⁵ atoms/cm³. The high temperature implantation process 240 is performed for any suitable amount of time, for example, about 5 minutes.

The high temperature implantation process 240 is performed at a temperature greater than room temperature (room temperature being about 20° C. to 25° C.). For example, the high temperature implantation process 240 is performed at a temperature greater than about 200° C. In the present embodiment, the high temperature carbon implantation process utilizes a temperature from about 200° C. and about 600° C. It has been observed that the high temperature implantation process 240 substantially (if not completely) eliminates defects in the substrate 210 caused by the PAI process 230. The high temperature provides a self-annealing characteristic, which leads to regions 242 including partially amorphized, partially crystallized regions, such that the substrate 210 includes less amorphized area. The high temperature implantation process 240 can reduce implant defects caused by the PAI process 230, thereby reducing a depth of the amorphized regions/layers.

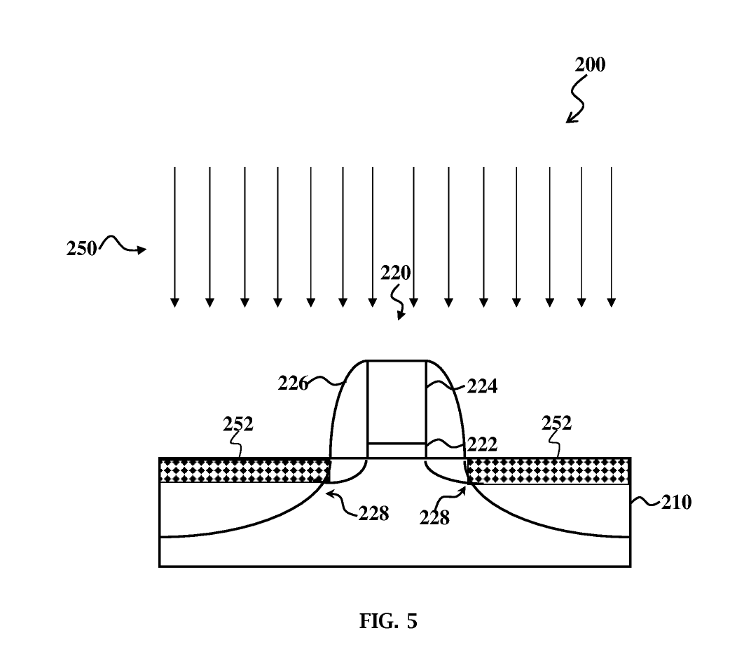

Referring to FIGS. 1 and 5, at block 108, an annealing process 250 is performed on the substrate 210. The annealing process 250 causes the regions 242 (in a partially amorphized, partially crystallized phase) to fully re-crystallize, forming stressor regions 252. This is often referred to as solid-phase epitaxy, and thus, the stressor regions 252 may be referred to as epi regions. In the present embodiment, the stressor regions 252 are Si:C stressor regions for an NMOS device. Alternatively, the stressor regions 252 could be SiGe stressor regions for a PMOS device. The annealing process 250 is a rapid thermal annealing (RTA) process or a millisecond thermal annealing process (for example, a millisecond laser thermal annealing process). In the present embodiment, the annealing process 250 is a high temperature anneal, utilizing a temperature greater than about 900° C. In an embodiment, the annealing process 250 utilizes a temperature up to a Si melting point of about 1,400° C. The anneal process 250 is also performed for a few milliseconds or less, for example for about 0.8 milliseconds to about 100 milliseconds.

As noted above, the high temperature implantation process 240 partially crystallizes the stressor regions, eliminating a substantial portion of the defects caused by the PAI process 230. Thus, the annealing process 250 can be performed at a high temperature for a short amount of time. If instead, the carbon implantation process was performed at room temperature, too many defects remain in the stressor regions 242, and then, the annealing process 250 is relied on to remedy the defects. However, when the time for performing the annealing process 250 is too long, carbon diffusion occurs, negatively effecting overall device performance, and when the time for performing the annealing process 250 is too short, too many defects remain, negatively effecting device performance. In the present embodiment, as also noted above, the high temperature implantation process 240 provides self-annealing characteristics, which reduces the amount of post-thermal treatment required for remedying any implantation defects. It is understood that different embodiments may have different advantages, and that no particular advantage is necessarily required of any embodiment.

Referring to FIG. 1, at block 110, fabrication of the semiconductor device 200 can be completed as briefly discussed below. The semiconductor device 200 may undergo further CMOS or MOS technology processing to form various features known in the art. For example, the method 100 may proceed to form main spacers. Contact features, such as silicide regions, may also be formed. The contact features may be coupled to the stressor regions 252. The contact features include silicide materials, such as nickel silicide (NiSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), other suitable conductive materials, and/or combinations thereof. The contact features can be formed by a process that includes depositing a metal layer, annealing the metal layer such that the metal layer is able to react with silicon to form silicide, and then removing the non-reacted metal layer. An inter-level dielectric (ILD) layer can further be formed on the substrate 210 and a chemical mechanical polishing (CMP) process is further applied to the substrate to planarize the substrate. Further, a contact etch stop layer (CESL) may be formed on top of the gate structure 220 before forming the ILD layer.

In an embodiment, the gate electrode 224 remains polysilicon in the final device. In another embodiment, a gate replacement process (or gate last process) is performed, where the polysilicon gate layer 224 is replaced with a metal gate. For example, a metal gate may replace the gate layer (i.e., polysilicon gate layer) of the gate structure 220. The metal gate includes liner layers, work function layers, conductive layers, metal gate layers, fill layers, other suitable layers, and/or combinations thereof. The various layers include any suitable material, such as aluminum, copper, tungsten, titanium, tantulum, tantalum aluminum, tantalum aluminum nitride, titanium nitride, tantalum nitride, nickel silicide, cobalt silicide, silver, TaC, TaSiN, TaCN, TiAl, TiAlN, WN, metal alloys, other suitable materials, and/or combinations thereof. In a gate last process, the CMP process on the ILD layer is continued to expose the poly gate layer 224 of the gate structure 220, and an etching process is performed to remove the gate layer 224 thereby forming trenches. The trench is then filled with a proper work function metal (e.g., p-type work function metal or n-type work function metal).

Subsequent processing may further form various contacts/vias/lines and multilayer interconnect features (e.g., metal layers and interlayer dielectrics) on the substrate 210, configured to connect the various features or structures of the semiconductor device 200. The additional features may provide electrical interconnection to the device. For example, a multilayer interconnection includes vertical interconnects, such as conventional vias or contacts, and horizontal interconnects, such as metal lines. The various interconnection features may implement various conductive materials including copper, tungsten, and/or silicide. In one example, a damascene and/or dual damascene process is used to form a copper related multilayer interconnection structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
providing a semiconductor substrate;
performing a pre-amorphous implantation process on the substrate;
performing a high temperature implantation process utilizing a temperature greater than about 200° C. on the substrate; and
performing an annealing process on the substrate.

2. The method of claim 1 wherein performing the high temperature implantation process includes implanting the substrate with carbon or germanium implant species.

3. The method of claim 1 wherein performing the high temperature carbon implantation process includes utilizing a temperature from about 500° C. to about 600° C.

4. The method of claim 1 wherein performing the annealing process includes performing a high temperature annealing process.

5. The method of claim 4 wherein performing the high temperature annealing process includes utilizing a temperature greater than about 900° C.

6. The method of claim 4 wherein performing the high temperature annealing process includes performing the annealing process for a few milliseconds (ms) or less.

7. The method of claim 1 wherein performing the annealing process includes utilizing a rapid thermal annealing process or laser thermal annealing process.

8. The method of claim 1 wherein performing the pre-amorphous implantation process includes implanting the substrate with a silicon or germanium implant species.

9. The method of claim 1 wherein performing the pre-amorphous implantation process includes utilizing an implantation energy from about 5 KeV to about 40 KeV.

10. The method of claim 1 wherein performing the high temperature carbon implantation process includes performing the high temperature implantation process for about 5 minutes.

11. A method comprising:
forming a gate structure over a substrate;
forming a source and drain region in the substrate, interposed by the gate structure;
performing a pre-amorphous implantation process on the source and drain region; and
thereafter, performing a high temperature carbon implantation process on the source and drain region.

12. The method of claim 11 further comprising performing a high temperature annealing process on the substrate.

13. The method of claim 12 wherein performing the high temperature annealing process includes utilizing a temperature from about 900° C. to about 1,400° C.

14. The method of claim 12 wherein performing the high temperature annealing process includes performing the annealing process from about 0.8 milliseconds to about 100 milliseconds.

15. The method of claim 11 wherein performing the high temperature carbon implantation process includes utilizing a temperature greater than room temperature.

16. The method of claim 15 wherein utilizing the temperature greater than room temperature includes utilizing a temperature from about 200° C. to about 600° C.

17. The method of claim 11 wherein performing the pre-amorphous implantation process includes implanting the source and drain region with a silicon implant species.

18. The method of claim 11 wherein performing the high temperature implantation process includes utilizing an implantation dosage of about 1×10¹³ atoms/cm³ to about 1×10¹⁷ atoms/cm³.

19. A method comprising:
forming a gate structure over a substrate;
forming a source and drain region in the substrate, adjacent the gate structure;
forming an amorphized region in the source and drain region;
implanting the amorphized region utilizing a temperature greater than about 200° C.; and
thereafter, performing a annealing process at a temperature greater than about 900° C., such that the amorphized region re-crystallizes and forms a stressor region.

20. The method of claim 19 wherein implanting the amorphized region utilizing the temperature greater than about 200° C. includes implanting the source and drain region with a carbon implant species.

21. The method of claim 19 wherein forming the stressor region includes forming a SiGe or Si:C stressor region.

22. The method of claim 19 wherein performing the annealing process includes performing the annealing process for a few milliseconds or less.
